(19) United States
(12) Patent Application Publication
(10) Pub. No.: US 2025/0075308 A1
(43) Pub. Date: Mar. 6, 2025

(54) OXIDE FILM AND OXIDE SPUTTERING TARGET

(71) Applicant: JX ADVANCED METALS CORPORATION, Tokyo (JP)

(72) Inventors: Hiroyoshi YAMAMOTO, Ibaraki (JP); Atsushi NARA, Ibaraki (JP)

(21) Appl. No.: 18/726,026

(22) PCT Filed: Nov. 21, 2022
(86) PCT No.: PCT/JP2022/043060

§ 371 Date: Jul. 1, 2024

(30) Foreign Application Priority Data
Jan. 5, 2022 (JP) 2022-000584

(51) Int. Cl. C23C 14/08; C23C 14/34

(52) U.S. Cl. CPC C23C 14/086; C23C 14/081; C23C 14/3414

(57) ABSTRACT

An object of the present disclosure is to provide an oxide film having low carrier concentration and high carrier mobility, and an oxide sputtering target suitable for forming such an oxide film. An oxide film containing zinc (Zn), tin (Sn), aluminum (Al), and oxygen (O), wherein the oxide film satisfies Formulas (1) to (3) below; provided that, in each of the following formulas, Al, Sn, and Zn respectively represent an atomic ratio of each element in the oxide film.

$$3 \times Sn / Zn < Al \qquad ( 1 )$$

$$Al / ( Al + Sn + Zn ) \leq 0.10 \qquad ( 2 )$$

$$0.33 \leq Sn / ( Sn + Zn ) \leq 0.6 \qquad ( 3 )$$

### TECHNICAL FIELD

The present disclosure relates to an oxide film and an oxide sputtering target.

### BACKGROUND ART

A Zn—Sn—O system (ZTO: Zinc-Tin-Oxide) is known as a material of transparent conductive films and oxide semiconductor films. A transparent conductive film is used, for example, in solar batteries, liquid crystal surface devices, touch panels and the like (Patent Document 1 and so on). Moreover, an oxide semiconductor film is used as a semiconductor layer (channel layer) of thin film transistors (TFT) (Patent Document 2 and so on). A ZTO-based film is normally deposited using a sputtering target made from a Zn—Sn—O-based oxide sintered body.

A Zn—Sn—O-based oxide film to which other metal elements are added is known. For example, Patent Documents 3 and 4 disclose the formation of a thin film using an oxide sputtering target prepared from zinc oxide, gallium oxide, and tin oxide. Patent Document 3 describes that its object is to prepare a sputtering target having low bulk resistance and high density, and provide a transparent amorphous oxide semiconductor film in which selective etching to a metallic thin film is possible.

### PRIOR ART DOCUMENTS

### Patent Documents

[Patent Document 1] Japanese Unexamined Patent Application Publication No. 2017-36198
[Patent Document 2] Japanese Unexamined Patent Application Publication No. 2010-37161
[Patent Document 3] Japanese Unexamined Patent Application Publication No. 2010-18457
[Patent Document 4] Japanese Unexamined Patent Application Publication (Translation of PCT Application) No. 2016-507004

### DISCLOSURE OF THE INVENTION

### Problems to be Solved by the Invention

With an oxide semiconductor film, there are demands for increasing carrier mobility in order to increase response speed. Carrier mobility has a positive correlation with carrier concentration, and higher the carrier concentration, higher the carrier mobility. Thus, while it is conceivable to increase the carrier concentration in order to increase the carrier mobility, if the carrier concentration is increased, there is a problem in that the power consumption will also increase. In recent years, the issue of power consumption has become notable pursuant to the miniaturization of semiconductor devices, and there are demands for reducing power consumption. Nevertheless, because there is a trade-off relationship between carrier mobility and power consumption, it is necessary to satisfy both carrier mobility and power consumption.

When a ZTO film is used as an oxide semiconductor film, there was a problem in that the power consumption is high due to the high carrier concentration. Thus, it is conceivable to lower the carrier concentration by adjusting the film composition. Nevertheless, when the carrier concentration is decreased, the carrier mobility will also decrease, and there was a problem in that the intended semiconductor properties could not be obtained.

In light of the foregoing circumstances, an object of the present disclosure is to provide an oxide film having low carrier concentration and high carrier mobility, and an oxide sputtering target suitable for forming such an oxide film.

### Means for Solving the Problems

One mode of the present disclosure capable of achieving the foregoing object is as shown below.

[1] An oxide film containing zinc (Zn), tin (Sn), aluminum (Al), and oxygen (O), wherein the oxide film satisfies Formulas (1) to (3) below; provided that, in each of the following formulas, Al, Sn, and Zn respectively represent an atomic ratio of each element in the oxide film.

$$3 \times Sn / Zn < Al \qquad ( 1 )$$

$$Al / ( Al + Sn + Zn ) \leq 0.10 \qquad ( 2 )$$

$$0.33 \leq Sn / ( Sn + Zn ) \leq 0.6 \qquad ( 3 )$$

[2] The oxide film according to [1] above, wherein the oxide film has a carrier mobility of 5.0 cm²/V·s or more.

[3] The oxide film according to [1] or [2] above, wherein the oxide film has a carrier concentration of 1.0×10¹⁸ cm⁻³ or less.

[4] The oxide film according to any one of [1] to [3] above, wherein the oxide film has a refractive index of 2.15 or less.

[5] The oxide film according to any one of [1] to [4] above, wherein the oxide film has an extinction coefficient of 0.02 or less.

[6] An oxide sputtering target containing zinc (Zn), tin (Sn), aluminum (Al), and oxygen (O), wherein the oxide sputtering target satisfies Formulas (4) to (6) below; provided that, in each of the following formulas, Al, Sn, and Zn respectively represent an atomic ratio of each element in the oxide film.

$$3 \times Sn / Zn < Al \qquad ( 4 )$$

$$Al / ( Al + Sn + Zn ) \leq 0.10 \qquad ( 5 )$$

$$0.33 \leq Sn / ( Sn + Zn ) \leq 0.5 \qquad ( 6 )$$

[7] The oxide sputtering target according to [6] above, wherein the oxide sputtering target has a relative density of 97% or higher.

[8] The oxide sputtering target according to [6] or [7] above, wherein the oxide sputtering target has an average crystal grain size of 10 μm or less.

[9] The oxide sputtering target according to any one of [6] to [8] above, wherein the oxide sputtering target has a volume resistivity of 10 Ω·cm or less.

### Effect of the Invention

According to the present disclosure, it is possible to yield a superior effect of being able to provide an oxide film having low carrier concentration and high carrier mobility. Moreover, according to the present disclosure, it is possible to yield a superior effect of being able to provide an oxide sputtering target suitable for forming an oxide semiconductor film having low carrier concentration and high carrier mobility.

The object and effect of the present disclosure are not limited to those specifically described above, and include those that will become apparent to those skilled in the art from the entire specification.

### BEST MODE FOR CARRYING OUT THE INVENTION

### [Oxide Film]

An oxide film according to an embodiment the present disclosure contains zinc (Zn), tin (Sn), aluminum (Al), and oxygen (O), and satisfies Formulas (1) to (3) below; provided that, in each of the following formulas, Al, Sn, and Zn respectively represent an atomic ratio of each element in the oxide film.

$$3 \times Sn / Zn < Al \qquad ( 1 )$$

$$Al / ( Al + Sn + Zn ) \leq 0.10 \qquad ( 2 )$$

$$0.33 \leq Sn / ( Sn + Zn ) \leq 0.6 \qquad ( 3 )$$

The oxide film according to this embodiment is an oxide film obtained by adding Al to ZTO (sometimes referred to as “AZTO”). As a result of including a predetermined amount of Al in the oxide film, it is possible to increase the carrier mobility while preventing the increase in the carrier concentration. With the oxide film according to this embodiment, the Al content is changed depending on the Sn/Zn relationship. This is because, when the Sn content is increased, the effect of Al will weaken and the carrier concentration will increase, and as a result the power consumption will increase more than anticipated. Specifically, the lower limit of the Al content is set to 3×Sn/Zn<Al.

In the oxide film according to this embodiment, the upper limit of the Al content is Al/(Al+Sn+Zn)≤0.10. This is because, if Al/(Zn+Sn+Al) exceeds 0.10, there is a problem in that the resistivity of the oxide film will become too high.

In the oxide film according to this embodiment, the content ratio of Sn and Zn is 0.33≤Sn/(Sn+Zn)≤0.60. If Sn/(Sn+Zn) is 0.33 or higher, variations in the film characteristics (carrier concentration, mobility, volume resistivity and the like) due to heat can be suppressed to be within a certain range upon annealing the film. Moreover, if Sn/(Sn+Zn) is 0.60 or less, the carrier concentration can be maintained low.

With the oxide film according to this embodiment, the carrier mobility is preferably 5.0 cm²/V·s or more, more preferably 10.0 cm²/V·s or more, and most preferably 12.0 cm²/V·s or more. The carrier mobility is preferably high in order to increase the response speed of the oxide film, and if the mobility is within the foregoing range, the intended semiconductor properties can be obtained.

With the oxide film according to this embodiment, the carrier concentration is preferably 1.0×10¹⁸ cm⁻³ or less, more preferably 1.0×10¹⁷ cm⁻³ or less, and most preferably 1.0×10¹⁶ cm⁻³ or less. Because the carrier concentration has a positive correlation with the carrier mobility, the carrier concentration is ideally high, but if the carrier concentration is too high, there is a problem in that the power consumption will increase. Accordingly, by adjusting the carrier concentration to fall within the foregoing range, the power consumption can be sufficiently reduced.

With the oxide film according to this embodiment, the refractive index of light having a wavelength of 405 nm is preferably 2.00 or more and 2.15 or less. As a result of causing the refractive index to fall within the foregoing numerical range, it is possible to yield the effect of preventing scattering caused by the mediums, and this is effective as a transparent conductive film.

With the oxide film according to this embodiment, the extinction coefficient of light having a wavelength of 405 nm is preferably 0.02 or less. As a result of causing the extinction coefficient to fall within the foregoing numerical range, it is possible to yield the effect of achieving high transparency, and this is effective as a transparent conductive film.

### [Oxide Sputtering Target]

With the sputtering method, because the film is deposited in a vacuum, the composition of the sputtering target (atomic ratio of metal components) is reflected in the film composition without any partial loss of the metal components configuring the sputtering target or the inclusion of other metal components during the deposition process. Thus, under normal circumstances, the composition of the sputtering target may be adjusted to match the intended film composition. Nevertheless, because the sputter rate varies depending on the constituent elements and crystal phase, it is necessary to decide the composition of the sputtering target in consideration of such variation.

The oxide sputtering target according to this embodiment contains zinc (Zn), tin (Sn), aluminum (Al), and oxygen (O), and satisfies Formulas (4) to (6) below; provided that, in each of the following formulas, Al, Sn, and Zn respectively represent an atomic ratio of each element in the oxide film.

$$3 \times Sn / Zn < Al \qquad ( 4 )$$

$$Al / ( Al + Sn + Zn ) \leq 0.10 \qquad ( 5 )$$

$$0.33 \leq Sn / ( Sn + Zn ) \leq 0.5 \qquad ( 6 )$$

Formulas (4) and (5) may be adjusted to have the same composition as the respective metal elements in the oxide semiconductor film. Meanwhile, with Formula (6), because the sputter rate of Zn is slower than that of Sn, the upper limit of Sn/(Sn+Zn) needs to be adjusted to Sn/(Sn+Zn)≤0.50.

With the oxide sputtering target according to this embodiment, the relative density is preferably 97% or higher, more preferably 98% or higher, and most preferably 99% or higher. A high density sputtering target can reduce the amount of particles that are generated during deposition.

The relative density is calculated based on the following formula.

Relative density (%)=(measured density)/(standard density)×100

The standard density is the value of density calculated from the theoretical density and mass ratio of the oxides of elements excluding oxygen in the respective constituent elements of the sputtering target, and the theoretical density of each oxide is as follows.
Theoretical density of Al₂O₃: 3.95 g/cm³
Theoretical density of SnO: 6.95 g/cm³
Theoretical density of ZnO: 5.61 g/cm³

The measured density is the value obtained by dividing the weight of the sputtering target by its volume, and is calculated using the Archimedes method.

With the oxide sputtering target according to this embodiment, the average crystal grain size is preferably 10 μm or less, and more preferably 5 μm or less. When the texture of the sputtering target is fine, the amount of particles that are generated during deposition can be reduced.

With the sputtering target according to this embodiment, the volume resistivity is preferably 10 Ω·cm or less, and more preferably 5 Ω·cm or less. When the volume resistivity of the sputtering target is low, deposition can be performed stably during DC (direct current) sputtering.

### [Production Method of Oxide Sputtering Target]

The oxide sputtering target according to this embodiment can be produced, for example, in the following manner. Nevertheless, the following production method is merely illustrative, and it should be understood that this embodiment is not limited to this production method. Moreover, the detailed explanation of known processes is omitted to avoid the production method from becoming unnecessarily unclear.

### (Mixing and Pulverization of Raw Materials)

As raw materials, a ZnO powder, a SnO powder and an Al₂O₃ powder are prepared, and these raw materials are weighed and mixed to obtain the intended compound ratio, and then pulverized. After pulverization, the resulting average particle diameter (D50) is preferably 1.5 μm or less.

### (Calcination of Mixed Powder)

The pulverized mixed powder is calcined at 1000° C. to 1300° C. for 4 to 7 hours. As a result of performing calcination, a composite oxide (Zn₂SnO₄ phase, ZnAl₂O₄ phase) can be obtained. Nevertheless, calcination is an arbitrary process.

### (Hot Press Sintering)

The thus obtained mixed powder or calcined powder is filled in a carbon mold, and subject to pressure sintering (hot press) in a vacuum or inert gas atmosphere. The hot press conditions are preferably set as follows; namely, sintering temperature of 950° C. to 1100° C., applied pressure of 200 to 300 kgf/cm², and holding time of 1 to 4 hours. This is because, when the sintering temperature is too low, a high density sintered body cannot be obtained, and when the sintering temperature is too high, compositional variation caused by the evaporation of ZnO will occur.

### (Surface Finishing)

By preparing an oxide sintered body based on the foregoing processes and subsequently subjecting the oxide sintered body to machining processes such as cutting and grinding, an oxide sputtering target can be produced.

### (Deposition)

By mounting a sputtering target on a deposition device and performing sputtering under the following conditions, an oxide semiconductor film can be deposited on a substrate. Nevertheless, the following deposition conditions are representative examples, and it should be understood that there is no intention of limiting the present disclosure to these deposition conditions.
Deposition principle: DC sputtering
Deposition device: ANELVASPL-500
Target size: Diameter 6 inches, thickness 5 mm
Substrate: Glass
Film thickness: 60 to 900 nm
Power: 2.74 to 5.48 W/cm²
Atmosphere: Ar+2% O₂, 0.5 Pa, 28 to 50 sccm

### EXAMPLES

The present invention is now explained based on the following Examples and Comparative Examples. Note that the following Examples are merely representative examples, and the present invention is not limited to these Examples in any way. In other words, the present invention is limited only based on the scope of its claims, and covers various modifications other than the Examples included in the present invention.

In the present disclosure, the various physical properties, including those of the Examples and Comparative Examples, were analyzed using the following measurement methods and measurement conditions.

### (Component Composition of Film)

Measuring principle: FE-EPMA quantitative analysis
Measuring device: JXA-8500F manufactured by JEOL
Measurement condition: Acceleration voltage 15 kV
Illumination current: 2×10⁻⁷ A
Beam diameter: 100 μm

### (Carrier Concentration of Film)

Measuring principle: Hall measurement
Measuring device: 8400 model manufactured by LakeShore
Measurement condition: Sample was measured after being annealed at 200° C.

### (Carrier Mobility of Film)

Measuring principle: Hall measurement
Measuring device: 8400 model manufactured by LakeShore
Measurement condition: Sample was measured after being annealed at 200° C.

### (Component Composition of Sputtering Target)

Method: ICP-OES (Inductively Coupled Plasma Optical Emission Spectrometry)
Device: SPS3500DD manufactured by SII

### (Volume Resistivity of Sputtering Target)

Measuring device: Resistivity meter Σ-5+
Measurement system: Constant current application system
Measurement method: DC four probe method

The volume resistivity was measured at one location at the center and four locations at 90-degree intervals near the outer periphery on the surface of the sputtering target, and the average value thereof was obtained.

### Examples 1 to 5

A ZnO powder, a SnO powder and an Al₂O₃ powder were prepared, these raw materials were blended to achieve the composition ratio of the sputtering target indicated in Table 1, and thereafter mixed. The thus obtained mixed powder was pulverized via wet pulverization (ZrO₂ beads were used) to achieve an average particle diameter (D50) of 1.5 μm or less, dried, and thereafter sieved using a sieve having a sieve opening of 500 μm.

Next, the pulverized powder was filled in a carbon mold, subject to hot press sintering under the conditions described in Table 1, and the thus obtained sintered body was machined to obtain a shape of a sputtering target (diameter of 6 inches).

The relative density, average crystal grain size and volume resistivity of the Zn—Sn—Al—O (AZTO) oxide sputtering target prepared above were measured. The results are shown in Table 1. As shown in Table 1, favorable results were obtained for all Examples 1 to 5 regarding relative density, average crystal grain size, and volume resistivity. Moreover, as a result of performing DC sputtering using this sputtering target, arcing did not occur during sputtering, and it was possible to perform sputtering stably.

TABLE 1

| | | | | | | | | | Sintering Conditions | |
|---|---|---|---|---|---|---|---|---|---|---|
| | | | | | | | | | Surface | |
| | Composition of Sputtering Target [Metallic Atom %] | | | | | | | | Pressure | |
| | Al | Zn | Sn | Total | Al/(Al + Zn + Sn) | 3*Sn/Zn | Sn/(Al + Zn + Sn) | Sn/(Zn + Sn) | (kgf/cm²) | Temperature |
| Example 1 | 5 | 63 | 32 | 100 | 0.05 | 1.52 | 0.32 | 0.34 | 250 | 1050° C. |
| Example 2 | 5 | 63 | 32 | 100 | 0.05 | 1.52 | 0.32 | 0.34 | 250 | 1000° C. |
| Example 3 | 10 | 45 | 45 | 100 | 0.10 | 3.00 | 0.45 | 0.50 | 250 | 1050° C. |
| Example 4 | 5 | 57 | 38 | 100 | 0.05 | 2.00 | 0.38 | 0.40 | 250 | 1050° C. |
| Example 5 | 5 | 48 | 48 | 100 | 0.05 | 3.00 | 0.48 | 0.50 | 250 | 1050° C. |

| | Sintering Conditions | | | | | Average | |
|---|---|---|---|---|---|---|---|
| | | Press | Theoretical | Archimedes | Relative | Grain | Volume |
| | | Time | Density | Density | Density | Size | Resistivity |
| | Atmosphere | (Hours) | [g/cm³] | [g/cm³] | [%] | [μm] | [Ω · cm] |
| Example 1 | Argon | 2 | 6.10 | 6.09 | 99.9 | 4.0 | 2.47 |
| Example 2 | Argon | 2 | 6.10 | 6.25 | 102.4 | 4.6 | 0.29 |
| Example 3 | Argon | 2 | 6.18 | 6.35 | 102.8 | 2.5 | 0.01 |
| Example 4 | Argon | 2 | 6.19 | 6.13 | 99.0 | 3.6 | 0.48 |
| Example 5 | Argon | 2 | 6.32 | 6.20 | 98.1 | 3.3 | 0.45 |

### Examples 6 to 17

A ZnSnO sputtering target and an Al₂O₃ sputtering target were prepared using the powder sintering method. These sputtering targets were mounted on a sputter device and simultaneous sputtering (co-sputtering) was performed to deposit a film. Note that the adjustment of the Al concentration in the film was performed by changing the sputter power applied to the ZnSnO and Al₂O₃ sputtering targets. The concentration adjustment of Zn and Sn in the film was performed by using four types of ZnSnO sputtering targets having different compositions.

As the four types of ZnSnO sputtering targets described above, the composition was changed in the following manner; specifically, Zn:Sn=66.7 at %: 33.3 at %, 60.0 at %: 40.0 at %, 50.0 at %: 50.0 at %, and 40 at %: 60 at %.

The carrier concentration, carrier mobility, refractive index, and extinction coefficient of the films obtained in Examples 6 to 17 were analyzed. As a result, in all cases the carrier concentration was 1.0×10¹⁸ cm⁻³ or less and the carrier mobility was 10.0 cm²/V·s or more, and the intended results were obtained. Moreover, in all cases the refractive index was 2.15 or less and the extinction coefficient was 0.02 or less, and favorable results were obtained. These results are shown in Table 2. Note that, while the refractive index and the extinction coefficient were not measured in Examples 6 to 11, it can be assumed that in all cases the refractive index satisfies 2.15 or less and the extinction coefficient satisfies 0.02 or less.

TABLE 2

| | | | | | | | | | Carrier | Refractive | |
|---|---|---|---|---|---|---|---|---|---|---|---|
| | Film Composition [Metallic Atom %] Measured Value | | | | | | | Mobility | Concen- | Index | Extinction |
| | Al | Zn | Sn | Total | 3*Sn/Zn | Al/(Al + Zn + Sn) | Sn/(Zn + Sn) | [cm²/V · s] | tration | [n] | Coefficient |
| Example 6 | 7 | 55 | 38 | 100 | 2.09 | 0.07 | 0.41 | 10.8 | 3.7E+16 | — | — |
| Example 7 | 3 | 58 | 39 | 100 | 2.02 | 0.03 | 0.40 | 18.4 | 1.4E+17 | — | — |
| Example 8 | 4 | 58 | 38 | 100 | 1.97 | 0.04 | 0.40 | 17.2 | 6.9E+16 | — | — |
| Example 9 | 5 | 57 | 38 | 100 | 2.00 | 0.05 | 0.40 | 16.2 | 3.1E+16 | — | — |
| Example 10 | 6 | 57 | 37 | 100 | 1.95 | 0.06 | 0.39 | 14.3 | 2.6E+16 | — | — |
| Example 11 | 8 | 56 | 36 | 100 | 1.93 | 0.08 | 0.39 | 12.9 | 6.0E+15 | — | — |
| Example 12 | 3 | 51 | 46 | 100 | 2.71 | 0.03 | 0.47 | 17.0 | 8.1E+17 | 2.10 | 0.013 |
| Example 13 | 8 | 46 | 46 | 100 | 2.96 | 0.08 | 0.50 | 12.5 | 1.0E+17 | 2.11 | 0.008 |
| Example 14 | 9 | 48 | 43 | 100 | 2.66 | 0.09 | 0.47 | 9.9 | 8.6E+14 | 2.10 | 0.006 |
| Example 15 | 5 | 41 | 54 | 100 | 4.00 | 0.05 | 0.57 | 14.0 | 2.9E+16 | 2.12 | 0.009 |
| Example 16 | 6 | 40 | 54 | 100 | 4.04 | 0.06 | 0.57 | 12.6 | 4.4E+17 | 2.12 | 0.010 |
| Example 17 | 9 | 38 | 52 | 100 | 4.11 | 0.10 | 0.58 | 11.3 | 1.2E+17 | 2.09 | 0.006 |
| Comparative Example 1 | 1 | 52 | 47 | 100 | 2.71 | 0.01 | 0.47 | 20.5 | 2.3E+18 | 2.12 | 0.017 |
| Comparative Example 2 | 3 | 42 | 55 | 100 | 3.93 | 0.03 | 0.57 | 16.1 | 2.7E+18 | — | — |
| Comparative Example 3 | 0 | 30 | 70 | 100 | 7.00 | 0.00 | 0.70 | 7.2 | 1.6E+19 | 2.18 | 0.052 |
| Comparative Example 4 | 0 | 43 | 57 | 100 | 3.98 | 0.00 | 0.57 | 14.0 | 1.1E+19 | 2.11 | 0.028 |
| Comparative Example 5 | 0 | 54 | 46 | 100 | 2.56 | 0.00 | 0.46 | 19.7 | 5.5E+18 | 2.12 | 0.020 |

### Comparative Examples 1 to 5

In Comparative Examples 1 to 5, a ZnSnO sputtering target and an Al₂O₃ sputtering target were mounted on a sputter device and simultaneous sputtering (co-sputtering) was performed to deposit a film as with Example 6. The Al concentration in the film and the concentration ratio of Zn and Sn in the film were adjusted in the same manner as with Example 6. The composition of the films of Comparative Examples 1 to 5 is shown in Table 2.

The carrier concentration, carrier mobility, refractive index, and extinction coefficient of the films obtained in Comparative Examples 1 to 5 were analyzed. As a result, the films of Comparative Examples 1 to 5 had high carrier mobility on the one hand, but also had high carrier concentration on the other hand.

### INDUSTRIAL APPLICABILITY

According to the present disclosure, it is possible to yield a superior effect of being able to provide an oxide film having low carrier concentration and high carrier mobility. Moreover, according to the present disclosure, it is possible to yield a superior effect of being able to provide an oxide sputtering target suitable for forming an oxide film having low carrier concentration and high carrier mobility. The oxide film according to the present invention is useful as a transparent conductive film of solar batteries, liquid crystal surface devices and touch panels, and as a semiconductor film for use as a TFT channel layer.

1. An oxide film containing zinc (Zn), tin (Sn), aluminum (Al), and oxygen (O), wherein the oxide film satisfies Formulas (1) to (3) below, has a carrier mobility of 10.0 cm²/V·s or more, and has a carrier concentration of 1.0×10¹⁸ cm⁻³ or less; provided that, in each of the following formulas, Al, Sn, and Zn respectively represent an atomic ratio of each element in the oxide film:
$$3 \times Sn / Zn < Al \qquad ( 1 )$$
$$Al / ( Al + Sn + Zn ) \leq 0.10 \qquad ( 2 )$$
$$0.33 \leq Sn / ( Sn + Zn ) \leq 0.6 . \qquad ( 3 )$$

2. The oxide film according to claim 1, wherein the oxide film has a carrier mobility of 12.0 cm²/V·s or more.

3. The oxide film according to claim 2, wherein the oxide film has a carrier concentration of 1.0×10¹⁷ cm⁻³ or less.

4. The oxide film according to claim 3, wherein the oxide film has a refractive index of 2.15 or less.

5. The oxide film according to claim 4, wherein the oxide film has an extinction coefficient of 0.02 or less.

6. An oxide sputtering target containing zinc (Zn), tin (Sn), aluminum (Al), and oxygen (O), wherein the oxide sputtering target satisfies Formulas (4) to (6) below, has a relative density of 98% or higher, has an average crystal grain size of 10 μm or less, and has a volume resistivity of 10 Ω·cm or less; provided that, in each of the following formulas, Al, Sn, and Zn respectively represent an atomic ratio of each element in the oxide film:
$$3 \times Sn / Zn < Al \qquad ( 4 )$$
$$Al / ( Al + Sn + Zn ) \leq 0.10 \qquad ( 5 )$$
$$0.33 \leq Sn / ( Sn + Zn ) \leq 0.5 . \qquad ( 6 )$$

7. The oxide sputtering target according to claim 6, wherein the oxide sputtering target has a relative density of 99% or higher.

8. The oxide sputtering target according to claim 7, wherein the oxide sputtering target has an average crystal grain size of 5 μm or less.

9. The oxide sputtering target according to claim 8, wherein the oxide sputtering target has a volume resistivity of 5 Ω·cm or less.

10. The oxide sputtering target according to claim 7, wherein the oxide sputtering target has a volume resistivity of 5 Ω·cm or less.

11. The oxide sputtering target according to claim 6, wherein the oxide sputtering target has an average crystal grain size of 5 μm or less.

12. The oxide sputtering target according to claim 6, wherein the oxide sputtering target has a volume resistivity of 5 Ω·cm or less.

13. The oxide film according to claim 3, wherein the oxide film has an extinction coefficient of 0.02 or less.

14. The oxide film according to claim 2, wherein the oxide film has an extinction coefficient of 0.02 or less.

15. The oxide film according to claim 2, wherein the oxide film has a refractive index of 2.15 or less.

16. The oxide film according to claim 15, wherein the oxide film has an extinction coefficient of 0.02 or less.

17. The oxide film according to claim 1, wherein the oxide film has a carrier concentration of 1.0×10¹⁷ cm⁻³ or less.

18. The oxide film according to claim 1, wherein the oxide film has a refractive index of 2.15 or less.

19. The oxide film according to claim 1, wherein the oxide film has an extinction coefficient of 0.02 or less.
